(19) United States
(12) Patent Application Publication
(10) Pub. No.: US 2025/0293034 A1
(43) Pub. Date: Sep. 18, 2025

(54) METHOD FOR PRODUCING A SCRIBE LINE IN A GERMANIUM SEMICONDUCTOR WAFER WITH SUPERIMPOSED III-V SEMICONDUCTOR LAYERS

(71) Applicant: AZUR SPACE Solar Power GmbH, Heilbronn (DE)

(72) Inventors: Wolfgang KOESTLER, Heilbronn (DE); Benjamin HAGEDORN, Ilsfeld (DE)

(73) Assignee: AZUR SPACE Solar Power GmbH, Heilbronn (DE)

(21) Appl. No.: 19/083,288

(22) Filed: Mar. 18, 2025

(30) Foreign Application Priority Data
Mar. 18, 2024 (DE) 10 2024 000 874.8

(51) Int. Cl. H01L 21/306

(52) U.S. Cl. CPC H01L 21/30604

(57) ABSTRACT

A method for producing a scribe line in a germanium semiconductor wafer with superimposed III-V layers. The germanium semiconductor wafer having a back and a front and is designed as a substrate. Multiple III-V layers are formed on the front and part of the III-V layers form a surface of the germanium semiconductor wafer. A first resist is structured or applied on the surface and during structuring the first resist-free areas are created for the formation of the scribe line. The layers superimposed on the front of the germanium semiconductor wafer are removed in the resist-free areas. A second resist is structured in the bottom area of the first trench-shaped structure. A part of the substrate is removed to lower part of the bottom area in a first trench-shaped structure and form two steps opposite each other.

This nonprovisional application claims priority under 35 U.S.C. § 119(a) to German Patent Application No. 10 2024 000 874.8, which was filed in Germany on Mar. 18, 2024, and which is herein incorporated by reference.

### BACKGROUND OF THE INVENTION

### Field of the Invention

The present invention relates to a method for producing a scribe line in a germanium semiconductor wafer with superimposed III-V semiconductor layers.

### Description of the Background Art

From EP 306 517 7 B1, which corresponds to US 2016/0260860, which is incorporated herein by reference, a method for producing a mesa trench in a germanium semiconductor wafer with superimposed III-V layers is known, wherein etching is carried out into the germanium substrate to produce the mesa trench.

The mesa trench separates an integrated protection diode formed in a first stack with a first number of III-V layers from a multi-junction solar cell formed in a second stack with a second number of III-V layers, wherein the first number of III-V layers is smaller than the second number of III-V layers. In other words, the first stack with the integrated protection diode has at least one p-n junction less than the second stack with the multi-junction solar cell. The two stacks are also mechanically and electrically connected via the substrate after dicing the semiconductor wafer. It is understood that the area for the mesa trench is not an area for the formation of a scribe line.

In general, the mesa trench is generated by means of a dry etching process, wherein the etching depth is adjusted over time and/or by the detection of an endpoint.

U.S. Pat. No. 6,103,970 A discloses a method and system for the efficient and compact mounting of a bypass diode on the front of a multiple-junction solar cell built on an n-doped germanium substrate. The bypass diode is mounted in a recess created on the front of the solar cell, which can have a cylindrical shape or a multi-sided shape with three or four sides, and is electrically connected to two contacts on the front of the solar cell, so that the production steps known from the prior art of turning the solar cell are unnecessary.

A method for producing a multi-junction solar cell on a GaAs wafer is described in US 2011/0030774 A1, which can be produced with rear contacts and has a contact structure that ensures a safe and reliable electrical connection of the front with the back of the solar cell. An active area of the solar cell is enclosed by a first trench-shaped structure. When a mesa structure is created, the first trench-shaped structure is enclosed by a second trench-shaped structure, which serves as a dicing line for the solar cell to be separated from the wafer.

### SUMMARY OF THE INVENTION

It is therefore an object of the invention to provide a method which advances the state of the art.

The object is achieved, in an example, by a method for producing a scribe line of a germanium semiconductor wafer with superimposed III-V layers.

The method is used to create a scribe line on a germanium semiconductor wafer with superimposed III-V layers.

The germanium semiconductor wafer has a diameter of at least 100 mm and a thickness of more than 80 μm.

Furthermore, the germanium semiconductor wafer has a back and a front and is designed as a substrate.

Several III-V layers can be formed on the front of the germanium semiconductor wafer, wherein some of the III-V layers form a surface of the germanium semiconductor wafer.

A total thickness of the III-V layers can be in a range between 1 μm and 80 μm or in a range between 2 μm and 40 μm or in a range between 3 μm and 15 μm.

In an initial photolithography process, a first resist is structured on the surface. During the structuring process, the first resist-free areas are created for the formation of the scribe line.

As an alternative to carrying out the first photolithography process, the first resist is applied in a structured manner by means of an initial printing process. One advantage of the first printing process, or of the printing process in comparison with the photolithography processes, is that there is no need for time-consuming exposure and development of the first resist. In other words, the first resist is applied only in the areas to be coated during the first printing process, i.e., the first resist is not applied in the areas for the formation of the scribe line.

In a subsequent process, the III-V layers superimposed on the surface of the germanium semiconductor wafer are wet-chemically removed in the resist-free areas in order to create a first trench-shaped structure with two side surfaces opposite each other and a bottom area on the surface of the germanium semiconductor wafer.

In a second photolithography process, after the first trench-shaped structure has been produced, a second resist is applied and structured in the bottom area of the first trench-shaped structure, so that an edge of the bottom area is covered, i.e., a striped resist-free area is created.

As an alternative to carrying out the second photolithography process, the second resist can be applied in a structured manner by means of a second printing process. An advantage of the second printing process is, inter alia, that there is no need for time-consuming exposure and development of the first resist. In other words, in the second printing process, the second resist is applied only in the areas to be coated, i.e., the second resist is not applied to the striped area of the bottom of the trench-shaped structure.

After structuring or after the structured application, part of the substrate is removed from the coating-free areas of the bottom area by means of a second wet etching step, in order to lower part of the bottom area in the first trench-shaped structure, thereby forming two steps opposite each other.

The first resist of the first photolithography process can have the same chemical composition or a different chemical composition than the second resist.

It is understood that the two steps can be created by means of the second wet etching step along the entire length of the first trench-shaped structure and that the two steps run in the bottom area along the respective side surfaces and the step is made of germanium as a whole.

Furthermore, it is understood that at least one continuous scribe line can be created on the surface of the semiconductor wafer, i.e., the germanium semiconductor wafer can be divided into at least two pieces.

A lattice structure can be formed on the surface of the germanium semiconductor wafer. It is understood that all scribe line areas on the surface of the semiconductor wafer can be formed along straight lines.

It should be noted that the first wet etching step and the second wet etching step can use different etching solutions or different acids. In the following, the two terms “etching solution” and “acid” are used synonymously.

In particular, the acid used in the first wet etching step can have a different composition from the etching solution used in the second wet etching step.

Furthermore, it should be noted that when the first wet etching step is carried out, the acid has a lower etching rate than the III-V layers. An advantage here is that the duration of wet etching is not sensitive to an etching of germanium, which means that the II-V layers can be removed reliably and, in particular, completely in the bottom area of the first trench-shaped structure.

In an example, in the first wet etching step, the acid has no, or a very low, etching rate as compared to germanium. This makes it particularly simple and dependable to expose the front of the germanium semiconductor wafer in the bottom area of the first trench-shaped structure.

It is understood that the term “III-V layers” refers to a sequence of layers of one III-V compound each, wherein at least two immediately consecutive layers have different stoichiometry and/or a different material composition.

In a further development, the III-V layers on the substrate were monolithically grown on the germanium substrate using MOVPE processes. In another further development, the III-V layers were grown directly on the substrate. In example, the III-V layers were epitaxially either lattice-matched to the substrate or were not matched to the substrate by incorporating a metamorphic buffer.

In another further development, the III-V layers comprise at least two partial solar cells or a maximum of four partial solar cells arranged on the Ge substrate. In this case, a Ge subcell is formed at the top of the substrate.

Another advantage of the method is that a scribe line can be reliably created on the surface of the semiconductor wafer in a simple and particularly cost-effective manner. In particular, time-consuming dry etching processes or laser ablation processes are unnecessary.

Surprisingly, it has been shown that by means of the first wet etching step, steep side surfaces can be formed in the first trench-shaped structure without underetching in the III-V layers. In other words, the width at the top of the first trench-shaped structure is only slightly larger or no greater than the width at the bottom of the first trench-shaped structure.

In a further development, the width at the top can be greater than the width of the trench-shaped structure in the bottom area in a range between 0.0 μm and 50 μm or in a range between 0.5 μm and 30 μm or in a range between 1.0 μm and 15 μm.

Since the two side surfaces each have no pitch angle above 90° or no underetching, the side surfaces can be reliably covered with a resist in the second photolithography process in order to protect the III-V layers on the side surfaces from an etch attack during the second wet etching step.

It should be noted that the term “steep side surfaces” can mean a pitch angle greater than 45° or a pitch angle in a range between 90° and 45°, starting from the bottom area. In other words, the side surfaces do not have an angle greater than 90°.

An advantage of etching germanium in the second etching process in the bottom area of the trench-shaped structure is that part of the germanium layer is removed, and the remaining layer thickness makes it easier to separate the germanium semiconductor wafer.

In a further development, when the first wet etching process is carried out, side surfaces with a pitch angle between 90° and 80° or with a pitch angle between 90° and 85° or exactly vertical, i.e., with a pitch angle of 90°, are created in a first approximation.

In another further development, the side surfaces can comprise III-V layers or consist predominantly, i.e., more than 50% of the surface, more than 90% of the surface, or the side surfaces consist exclusively of III-V layers.

Preferably, the separation can be carried out by means of a dicing line from the back of the germanium semiconductor wafer, by which the germanium semiconductor wafer is divided into at least two parts. It should be noted that prior to separation, a plastic film is placed on the surface of the semiconductor wafer.

Furthermore, it should be noted that the first trench-shaped structure with the steps in the bottom area can be formed in the entire scribe line, wherein the scribe line extends on the surface at least from one edge of the germanium semiconductor wafer along a straight line to an opposite edge.

In a further development, the topography resulting from the first etching process on the side surfaces remains unchanged until the application of the second resist during the second photolithography process.

It is understood that the topography of the side surfaces is unchanged even after the resist has been removed from the second photolithography process, and the surface has the same topography after the first etching process.

It should also be noted that in the first photolithography process or in the printing process on the surface during the first etching step, only the scribe line areas are free of resist.

In a further development, the first resist in the printing process can have a different chemical composition than the first resist, which is used in the first photolithography process.

In another further development, the III-V layers formed on the front of the germanium semiconductor wafer comprise at least one solar cell, with an np-junction.

In an example, the III-V layers comprise binary and/or ternary and/or quaternary compounds, or the III-V layers consist of binary and/or ternary and/or quaternary compounds. In particular, the III-V layers comprise or consist of GaAs, InGaAs, (Al)InGaP, AlAs, or InP and include dopants such as carbon and/or silicon.

In an example, the thickness of a single III-V layer can be between 0.01 μm and 30 μm.

In a further development, the number of III-V layers arranged on top of each other is between 10 and 300 or between 20 and 150 or between 30 and 75.

In an example, all or at least 90% of the III-V layers can be deposited over the entire surface. Preferably, the III-V layers are deposited by means of a gas-phase epitaxy method such as MOVPE.

In an example, the same number of pn-junctions can be formed on the entire surface.

In another further development, the III-V layers formed on the front of the germanium semiconductor wafer can comprise a multi-junction solar cell.

In an example, the multi-junction solar cell has exactly two or exactly three and a maximum of five partial solar cells stacked on top of each other, wherein the partial solar cells are electrically connected in series by means of tunnel diodes formed between the partial solar cells.

In another further development, an n-layer can be formed on the front of the germanium semiconductor wafer by means of diffusion of dopants. This also allows for a Ge-partial solar cell to be formed in the germanium semiconductor wafer.

It is understood that the solar cell stack is the lowest partial solar cell, with the lowest partial solar cell having the smallest band gap in the multi-junction solar cell and absorbing in the red and infrared wavelength range.

In a further development, the germanium semiconductor wafer or the Ge semiconductor substrate is p-doped.

In an example, an np-junction is formed at the front of the germanium semiconductor wafer (WF), wherein the n-doped germanium layer is completely removed by means of the second wet etching step, so that only the p-doped substrate (SUB) is formed in the bottom area.

In an example, a metamorphic buffer can be formed between the lowest partial solar cell and the immediately following further partial solar cell, wherein the further partial solar cell and the metamorphic buffer consist of III-V layers or at least comprise them.

In a further development, at least the side surfaces are completely covered by the second resist when the second wet etching step is carried out and are thus completely protected from an etch attack in the second wet etching step.

In an example, during the second wet etching step, the surface can be completely covered with the second resist in addition to the side surfaces, thus protecting it from an etch attack. In other words, in the second photolithography process, the surface is completely covered with the second resist, except for the resist-free surfaces in the bottom area.

In a further development, in the second photolithography process, the back can be covered with a protective layer, preferably with another resist, to prevent etching on the back of the germanium semiconductor wafer.

In a further development, the first photolithography process or printing process may only be used after the formation of a first metal contact system on the surface and/or only after the formation of a metal contact system on the back.

In a further development, the two steps can be spaced at least 40 μm and a maximum of 200 μm apart.

In a further development, the steps can have a step height in a range between 0.05 μm and 10 μm or between 0.2 μm and 5 μm or between 0.3 μm and 2 μm. In a further development, the step height is in a range between 0.05 μm and 30 μm or in a range between 1 μm and 10 μm.

In an example, the steps can have a depth, i.e., a step surface in a range between 0.1 μm and 20 μm, or in a range between 0.2 μm and 10 μm, or in a range between 0.3 μm and 5 μm, or in a range between 0.2 μm and 195 μm or between 2 μm and 60 μm.

In a further development, the upper edge of the scribe line can have a width in a range between 40 μm and 500 μm.

In an example, when the first wet etching step is carried out, the III-V layers in the resist-free areas can be completely removed and the bottom area is preferably formed exclusively by the front of the germanium semiconductor wafer.

In an example, in the first photolithography process, the first resist can be formed over the entire surface of the germanium semiconductor wafer in a first process step, and in a second process step, the first resist is exposed and developed in order to produce resist-free areas.

In an example, the acid can have a selectivity greater than 10:1 or greater than 30:1 or greater than 50:1 in the first etching step, i.e., the III-V layers are etched by the acid at least ten times or at least thirty times or at least fifty times faster than germanium.

In an example, when the second wet etching step is carried out, the acid can have an etching rate that is as high as or higher than that of the III-V layers.

The first photolithography process and also the second photolithography process can include, among other things, a coating step with a resist, a curing step, an exposure step with a mask, a developing step with removal of the resist in the exposed areas—if a positive resist is used.

If a printing process is carried out instead of the first photolithography process, it is sufficient if a curing step takes place after the structured application of the first resist. The exposure step and developing step are omitted. It is understood that when using the printing process, the application of the first resist is equivalent to the application of a positive resist in the first photolithography process.

Subsequently, the respective wet etching is carried out in a further method step and then the resist is completely removed from the non-exposed areas by means of an ashing step and a cleaning step.

In a further development, the width of the scribe line can be determined by forming the first resist on the surface of the semiconductor wafer over the entire surface in a first process step of the first photolithography process, and by exposing and developing the first resist using a mask in a second method step, or alternatively by means of the first printing process, the first resist is formed in a structured manner on the surface of the semiconductor wafer.

Further scope of applicability of the present invention will become apparent from the detailed description given hereinafter. However, it should be understood that the detailed description and specific examples, while indicating preferred embodiments of the invention, are given by way of illustration only, since various changes, combinations and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1a to 1i show a cross-section of the process sequence for the production of a scribe line,

FIG. 2a shows a top view of a semiconductor wafer after the first etching step,

FIG. 2b shows an enlarged section of FIG. 2a,

FIG. 2c shows a cross-sectional view of the first trench-shaped structure according to FIG. 2a on a germanium semiconductor wafer after the first etching step,

FIG. 3a shows a top view of a semiconductor wafer after the second etching step,

FIG. 3b shows an enlarged section of FIG. 3a,

FIG. 3c shows a cross-sectional view of the first trench-shaped structure according to FIG. 3a on a germanium semiconductor wafer after the second etching step.

### DETAILED DESCRIPTION

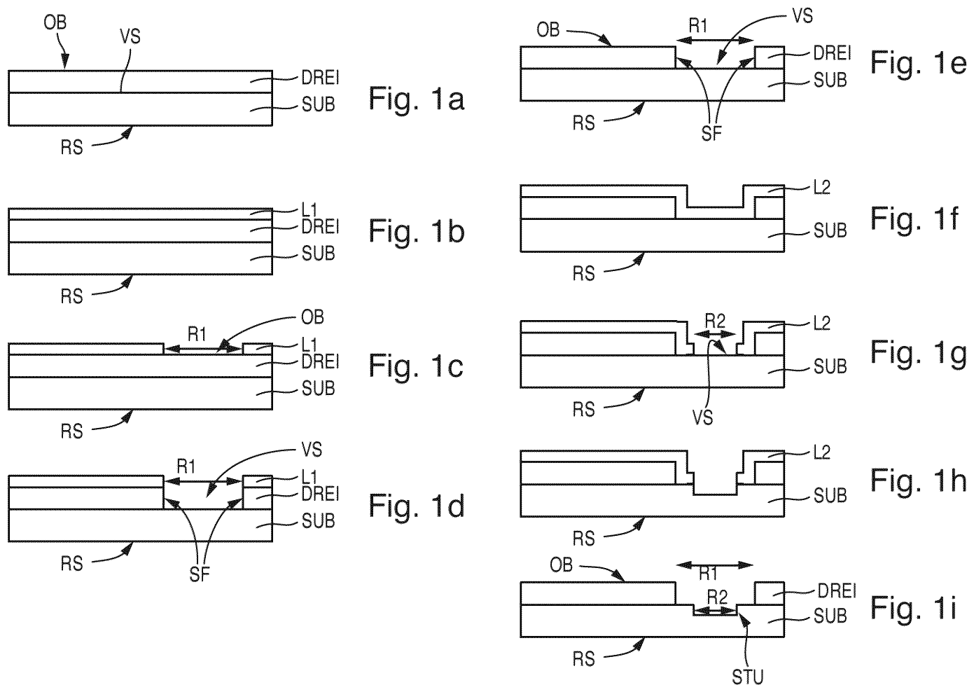

FIGS. 1a to 1i show the individual method steps in a cross-sectional view. It is understood that all method steps are carried out on a semiconductor wafer WF and that the cross-sectional illustrations only show the production of a single scribe line for reasons of clarity.

Furthermore, the two photolithography processes can each be replaced by a printing process and the number of process steps can be significantly reduced. The production of the scribe line using the two photolithography processes is explained below.

In a first step, shown in FIG. 1a, a germanium semiconductor wafer is provided as a substrate SUB with a front VS and a back RS. On the front VS, a superimposed layer sequence DREI of III-V layers is formed.

The layer sequence DREI was grown by epitaxy and comprises a large number of III-V layers made of different materials and dopings and has a surface OB. For reasons of clarity, the individual III-V layers are not shown in the superimposed layer sequence DREI.

In a second step, shown in FIG. 1b, as part of a first photolithography process, the surface OB is coated over the entire surface with a first resist L1. In the present case, a positive resist is used for this purpose.

In a third step, shown in FIG. 1c, after exposure and development of the first resist in a first area R1 on the surface OB, the first resist L1 is removed.

In a fourth step, shown in FIG. 1d, after a first wet etching step, the III-V layers in the first area R1 are etched away, so that the bottom area of the trench-shaped structure is formed on the front VS.

In a fifth step, shown in FIG. 1e, the first resist L1 is completely removed, so that a first trench-shaped structure is formed on the surface OB in the first area R1. The first trench-shaped structure has almost vertically formed side surfaces SF. The side surfaces SF consist of the III-V layers.

In a sixth step, shown in FIG. 1f, in a second photolithography process, the surface OB and the trench-shaped structure with the bottom area and the side surfaces SF are covered with a second resist L2.

In a seventh step, shown in FIG. 1g, the second resist L2 is removed from the bottom area of the trench-shaped structure in a second area R2, wherein the second resist covers the surface OB and the side surfaces SF and an edge of the bottom area. The width of the second area R2 is less than the width of the first area R1.

In an eighth step, shown in FIG. 1h, a part of the germanium layer on the front VS is etched away by means of a second wet etching step in the second area R2, so that two opposite steps STU made of germanium are formed in the bottom area.

In a ninth step, shown in FIG. 1i, the second resist L2 is completely removed and the scribe line structure with the step STU in the bottom area is fully formed.

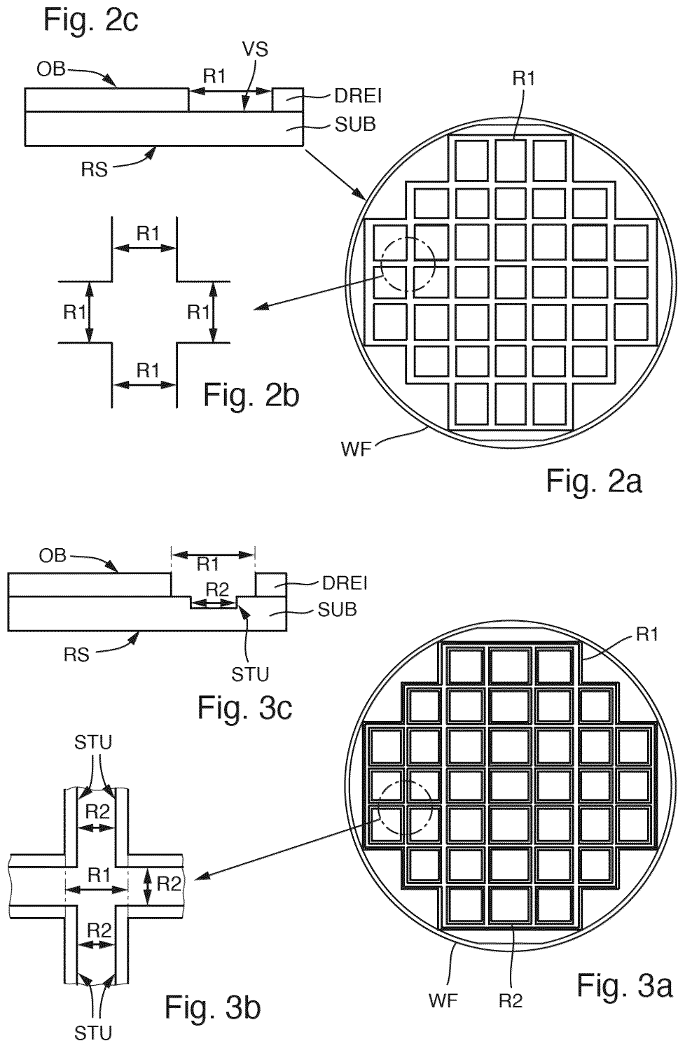

FIG. 2a shows a top view of a germanium semiconductor wafer WF after the first etching step and after the removal of the first resist L1. In the following, only the differences to the previous figures are explained.

On the surface of the germanium semiconductor wafer WF, a large number of scriber line areas with the width R1 are formed.

An enlarged representation of the top view of FIG. 2a is shown in FIG. 2b.

To illustrate this, FIG. 2c shows a cross-section of the first trench-shaped structure. Here, the cross-section in FIG. 2c corresponds to the embodiment shown in FIG. 1e.

FIG. 3a shows a top view of the germanium semiconductor wafer WF after the second etching step and after the removal of the second resist L2. In the following, only the differences to FIG. 2a are explained.

An enlarged representation of the top view of FIG. 3a is shown in FIG. 3b.

To illustrate this, FIG. 3c shows a cross-section of the trench-shaped structure, i.e., the finished scribe line. Here, the cross-section in FIG. 3c corresponds to the embodiment shown in FIG. 1i.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for producing a scribe line in a germanium semiconductor wafer with superimposed III-V layers, the germanium semiconductor wafer having a diameter of at least 100 mm and a thickness of more than 80 μm, the germanium semiconductor wafer having a back and a front and is designed as a substrate, multiple III-V layers are formed on the front and part of the III-V layers form a surface of the germanium semiconductor wafer, the method comprising:
structuring, in a first photolithography process, a first resist on the surface and during structuring the first resist-free areas are created for the formation of the scribe line, or the first resist is applied in a structured manner via a first printing process;
removing, in a subsequent process, the layers superimposed on the front of the germanium semiconductor wafer in the resist-free areas by a wet chemical process in order to create a first trench-shaped structure with two side surfaces opposite each other and a bottom area on the front of the germanium semiconductor wafer;
structuring, via a second photolithography process, a second resist in the bottom area of the first trench-shaped structure, in such a way that an edge of the bottom area is covered, or via a second printing process, the second resist is applied in a structured manner such that an edge of the bottom area is covered; and
removing, in second resist-free areas of the bottom area of the first trench-shaped structure, a part of the substrate via a second wet etching step, in order to lower part of the bottom area in the first trench-shaped structure and form two steps opposite each other, with the two steps running along the respective side surface.

2. The method for producing a scribe line according to claim 1, wherein, during the first wet etching step outside the scribe line areas to be produced, the surface is protected from an etch attack by the first resist.

3. The method for producing a scribe line according to claim 1, wherein during the second wet etching step the surface and the side surface of the first trench-shaped structure are protected from etch attack by a second resist.

4. The method for producing a scribe line according to claim 1, wherein the two steps opposite each other are formed in the bottom area in the second wet etching step, wherein the two steps are spaced at least 10 μm and at a maximum 400 μm or 20 μm to 200 μm apart and have a step height in a range between 0.05 μm and 10 μm or between 0.2 μm and 5 μm or between 0.3 μm and 2 μm.

5. The method for producing a scribe line according to claim 1, wherein the scribe line has a width in a range between 40 μm and 500 μm.

6. The method for producing a scribe line according to claim 1, wherein, when the first wet etching step is carried out, the III-V layers in the resist-free areas are completely removed and the bottom area is formed by the front of the germanium semiconductor wafer.

7. The method for producing a scribe line according to claim 1, wherein the width of the scribe line is determined by forming the first resist on the surface of the germanium semiconductor wafer over the entire surface in a first process step in the first photolithography process and exposing and developing the first resist via a mask in a second process step or by forming the first resist on the surface of the germanium semiconductor wafer in a structured manner via the first printing process.

8. The method for producing a scribe line according to claim 1, wherein the side surfaces include III-V layers or consist of III-V layers.

9. The method for producing a scribe line according to claim 1, wherein, in the first etching step, the acid has a selectivity greater than 10:1 to etch the III-V layers much faster than germanium.

10. The method for producing a scribe line according to claim 1, wherein on the front of the germanium semiconductor wafer, an np-junction is formed and the n-doped germanium layer is completely removed via the second wet etching step, so that only a p-doped substrate is formed in the bottom area.

11. The method for producing a scribe line according to claim 1, wherein the step surface has a width in a range between 0.2 μm and 195 μm or between 2 μm and 60 μm.

12. The method for producing a scribe line according to claim 1, wherein a step height is in a range between 0.05 μm and 30 μm or in a range between 1 μm and 10 μm.

13. The method for producing a scribe line according to claim 1, wherein the III-V layers formed on the front have a total thickness between 1 μm and 80 μm or a total thickness between 2 μm and 40 μm or a total thickness between 3 μm and 15 μm.
